(19) United States
(12) Patent Application Publication
(10) Pub. No.: US 2025/0228125 A1
(43) Pub. Date: Jul. 10, 2025

(54) LIGHT EMITTING ELEMENT, METHOD FOR MANUFACTURING THE LIGHT EMITTING ELEMENT, AND DISPLAY DEVICE COMPRISING THE LIGHT EMITTING ELEMENT

(71) Applicants: Samsung Display Co., Ltd., Yongin-si (KR); Hongik University Industry-Academia Cooperation Foundation, Seoul (KR)

(72) Inventors: Chang Yeol HAN, Yongin-si (KR); Heesun YANG, Seoul (KR); Suk-Young YOON, Seoul (KR); Hyungmin YANG, Seoul (KR)

(73) Assignees: Samsung Display Co., Ltd., Yongin-si (KR); Hongik University Industry-Academia Cooperation Foundation, Seoul (KR)

(21) Appl. No.: 18/895,595

(22) Filed: Sep. 25, 2024

(30) Foreign Application Priority Data
Jan. 4, 2024 (KR) 10-2024-0001359

(51) Int. Cl. H10K 85/30; H10K 50/165; H10K 71/15

(52) U.S. Cl. CPC H10K 85/381; H10K 50/165; H10K 71/15

(57) ABSTRACT

Embodiments provide a light-emitting element that includes a first electrode, a light-emitting layer disposed on the first electrode, the light-emitting layer including a quantum dot, a second electrode disposed on the light-emitting layer, a hole transport region disposed between the first electrode and the second electrode, and an electron transport region disposed between the first electrode and the second electrode, the electron transport region including a metal nanoparticle. The light-emitting layer is disposed between the hole transport region and the electron transport region. The metal nanoparticle includes a core including a metal oxide, and a ligand bonded to the core. The ligand may include bisulfite derived from an ionic compound represented by Formula A-1, which is explained in the specification.

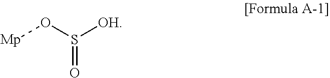

### CROSS-REFERENCE TO RELATED APPLICATION(S)

This application claims priority to and benefits of Korean Patent Application No. 10-2024-0001359 under 35 U.S.C. § 119, filed on Jan. 4, 2024, in the Korean Intellectual Property Office, the entire contents of which are incorporated herein by reference.

### BACKGROUND

### 1. Technical Field

The disclosure relates to a light-emitting element including metal nanoparticles, a method for manufacturing the light-emitting element, and a display device including the light-emitting element.

### 2. Description of the Related Art

A light-emitting element has characteristics of converting electric energy into light energy. Among light-emitting elements, a quantum-dot light-emitting element that includes quantum dots has high color purity and high luminous efficiency, and may be multicolored. Holes generated in the light-emitting element move to a light-emitting layer via a hole transport region, and electrons generated in the light-emitting element move to the light-emitting layer via an electron transport region. Research on facilitating injection and transport of the holes and electrons in the quantum-dot light-emitting element has been conducted in order to improve luminous efficiency.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a highly efficient light-emitting element and a display device including the same.

The disclosure also provides a method for manufacturing a light-emitting element which is excellent in manufacturing efficiency.

According to an embodiment, a light-emitting element may include a first electrode, a light-emitting layer disposed on the first electrode, the light-emitting layer including a quantum dot, a second electrode disposed on the light-emitting layer, a hole transport region disposed between the first electrode and the second electrode, and an electron transport region disposed between the first electrode and the second electrode, the electron transport region including a metal nanoparticle, wherein
the light-emitting layer may be disposed between the hole transport region and the electron transport region, the metal nanoparticle may include a core including a metal oxide, and a ligand bonded to the core, the ligand may include bisulfite derived from an ionic compound represented by Formula A-1:

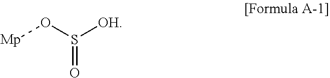

In Formula A-1, Mp may be Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba; and [symbol] represents an ionic bond.

In an embodiment, the ligand may include a first ligand including the bisulfite in Formula A-1, and a second ligand including Mp in Formula A-1.

In an embodiment, the first ligand and the second ligand may each be bonded to a surface of the core.

In an embodiment, a number of moles of the bisulfite may be in a range of about 5 mol % to about 20 mol %, based on 100 mol % of a total number of moles of the metal nanoparticle.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.5; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba.

In an embodiment, the quantum dot may not include cadmium.

In an embodiment, the hole transport region may be disposed between the first electrode and the light-emitting layer, and the electron transport region may be disposed between the light-emitting layer and the second electrode.

In an embodiment, the hole transport region may be disposed between the light-emitting layer and the second electrode, and the electron transport region may be disposed between the first electrode and the light-emitting layer.

According to an embodiment, a method for manufacturing a light-emitting element may include: forming a first electrode; forming a light-emitting layer on the first electrode; forming a second electrode on the light-emitting layer; forming a hole transport region; and forming an electron transport region by providing a composition including a metal nanoparticle, wherein
one step among the forming of the hole transport region and the forming of the electron transport region may be performed between the forming of the first electrode and the forming of the light-emitting layer, and the remaining step may be performed between the forming of the light-emitting layer and the forming of the second electrode; and the metal nanoparticle may include a core including a metal oxide, and a ligand bonded to the core, the ligand including bisulfite derived from an ionic compound represented by Formula A-1:

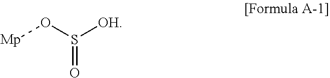

In Formula A-1, Mp may be Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba; and [symbol] represents an ionic bond.

In an embodiment, the method may further include producing the metal nanoparticle before the forming of the electron transport region, wherein

the producing of the metal nanoparticle may include producing the core, and providing the ionic compound to the core to produce the metal nanoparticle in which the ligand is bonded to a surface of the core.

In an embodiment, the producing of the core may include: preparing a solution having a first metal precursor including a first metal, a second metal precursor including a second metal different from the first metal, and a first solvent; and providing, to the solution, a second solvent different from the first solvent, and
the first metal and the second metal may each independently include Li, Be, Na, Mg, Al, K, Ca, Ta, Ti, V, Cr, Mn, Fe, Co, Ni, Cu, Ga, Ge, Rb, Sr, Zr, Nb, Mo, Ru, Rh, Pd, Ag, In, Sn, Sb, or Ba.

In an embodiment, the first metal precursor may be a zinc precursor, the second metal precursor may be a magnesium precursor, and the zinc precursor and the magnesium precursor may each independently include an acetate ion or a halogen ion.

In an embodiment, the first solvent may include at least one of ethanol and dimethyl sulfoxide (DMSO).

In an embodiment, the second solvent may include at least one of potassium hydroxide, sodium hydroxide, trimethylammonium hydroxide (TMAM), and tetramethylammonium hydroxide (TMAH).

In an embodiment, a number of moles of the bisulfite may be in a range of about 5 mol % to about 20 mol %, based on 100 mol % of a total number of moles of the metal nanoparticle.

In an embodiment, the composition may be provided through an inkjet printing method or a dispensing method.

According to an embodiment, a display device may include a display element layer disposed on a base layer, the display element layer including a light-emitting element, wherein
the light-emitting element may include: a first electrode; a light-emitting layer disposed on the first electrode, the light-emitting layer including a quantum dot; a second electrode disposed on the light-emitting layer; a hole transport region disposed between the first electrode and the second electrode; and an electron transport region disposed between the first electrode and the second electrode, the electron transport region including a metal nanoparticle, the light-emitting layer may be disposed between the hole transport region and the electron transport region, and the metal nanoparticle may include a core including a metal oxide, and a ligand bonded to the core, the ligand including bisulfite derived from an ionic compound represented by Formula A-1:

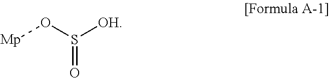

In Formula A-1, Mp may be Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba; and [symbol] represents an ionic bond.

In an embodiment, the ligand may include a first ligand including the bisulfite in Formula A-1, and a second ligand including Mp in Formula A-1.

In an embodiment, the first ligand and the second ligand may each be bonded to a surface of the core.

In an embodiment, a number of moles of the bisulfite may be in a range of about 5 mol % to about 20 mol %, based on 100 mol % of a total number of moles of the metal nanoparticle.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.5; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view of a part corresponding to line I-I′ of FIG. 1;

FIG. 3 is a schematic plan view of a display device according to an embodiment;

FIG. 4A is a schematic cross-sectional view of a part corresponding to line II-II′ of FIG. 3;

FIG. 4B is a schematic cross-sectional view of a display device according to an embodiment;

FIG. 5A is a schematic cross-sectional view of a light-emitting element according to an embodiment;

FIG. 5B is a schematic cross-sectional view of a light-emitting element according to an embodiment;

FIG. 5C is a schematic cross-sectional view of a light-emitting element according to an embodiment;

FIG. 5D is a schematic cross-sectional view of a light-emitting element according to an embodiment;

FIG. 6 is a schematic cross-sectional view of a metal nanoparticle according to an embodiment;

FIG. 7 is an enlarged schematic view of region XX′ of FIG. 6;

FIG. 8A is a graph of the result of evaluating a light-emitting element of Example;

FIG. 8B is a graph of the result of evaluating a light-emitting element of Example;

FIG. 8C is a graph of the result of evaluating a light-emitting element of Example;

FIG. 9A is a flowchart of a method for manufacturing a light-emitting element according to an embodiment;

FIG. 9B is a flowchart of a method for manufacturing a light-emitting element according to an embodiment;

FIG. 10 is a schematic diagram of a step of manufacturing a light-emitting element according to an embodiment;

FIG. 11A is a schematic diagram of a step of manufacturing a light-emitting element according to an embodiment;

FIG. 11B is a schematic diagram of a step of manufacturing a light-emitting element according to an embodiment; and

FIG. 12 is an enlarged schematic view of region AA′ of FIG. 11A.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

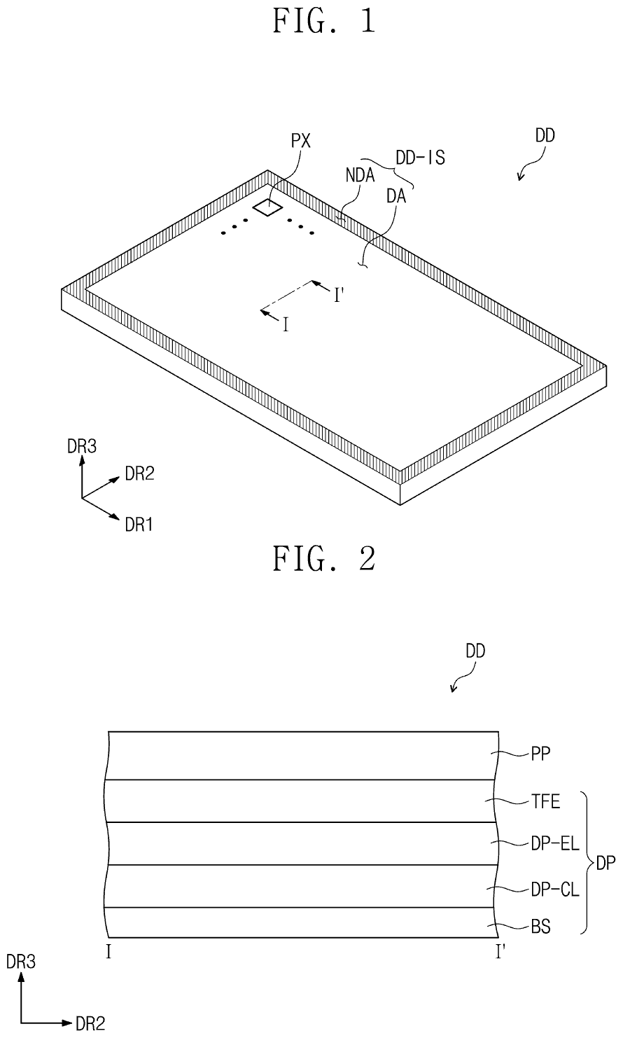

Hereinafter, a light-emitting element according to an embodiment and a display device including the light-emitting element will be described with reference to the accompanying drawings. FIG. 1 is a schematic perspective view of a display device according to an embodiment.

Referring to FIG. 1, a display device DD according to an embodiment may be activated in response to electrical signals. For example, the display device DD may be a large apparatus such as a television, a monitor, or a billboard. In an embodiment, the display device DD may be a small or medium-sized apparatus such as a personal computer, a laptop computer, a personal digital assistant, a car navigation unit, a game console, a smartphone, a tablet computer, or a camera. However, these are only provided as examples, and the display device DD may also be included in other devices.

The display device DD may display an image (or video) through a display surface DD-IS. The display surface DD-IS may be parallel to a plane that is defined by a first directional axis DR1 and a second directional axis DR2. The display surface DD-IS may include a display region DA and a non-display region NDA.

A pixel PX may be disposed in the display region DA, and the pixel PX may not be disposed in the non-display region NDA. The non-display region NDA may be defined along a border of the display surface DD-IS. The non-display region NDA may surround the display region DA. However, embodiments are not limited thereto. For example, the non-display region NDA may be omitted, or disposed only on one side of the display region DA.

FIG. 1 shows that the display device DD may include a flat-type display surface DD-IS, but embodiments are not limited thereto. For example, in embodiments, the display surface DD-IS of the display device DD may be a curved display surface or a three-dimensional display surface. The three-dimensional display surface may include multiple display regions disposed in different directions.

In FIG. 1 and the following drawings, the first directional axis DR1, a second directional axis DR2, and/or a third directional axis DR3 are illustrated. In the specification, directions indicated by the first to third directional axes DR1, DR2, and DR3 are relative terms, and may thus be changed into other directions. The directions indicated by the first to third directional axes DR1, DR2, and DR3 may be described as the first to third directions, and may be denoted by the same reference symbols or numerals. In the specification, the first directional axis DR1 and the second directional axis DR2 may cross at right angles, and the third directional axis DR3 may be a normal direction of a plane that is defined by the first directional axis DR1 and the second directional axis DR2.

In the specification, a plan view may refer to the plane defined by the first directional axis DR1 and the second directional axis DR2, and a cross-sectional view may refer to a surface that is perpendicular to the plane defined by the first directional axis DR1 and the second directional axis DR2 and is parallel to the third directional axis DR3. A thickness direction of the display device DD may be a direction parallel to the third direction DR3 that is a normal direction of the plane defined by the first direction DR1 and the second direction DR2.

In the specification, an upper surface (or front surface) and a lower surface (or rear surface) of each of the members constituting the display device DD may be defined on the basis of the third direction DR3. For example, a surface that is relatively adjacent to the display surface DD-IS, among two surfaces with one member facing each other with respect to the third direction DR3, may be defined as the front surface (or upper surface), and a surface that is relatively spaced apart from the display surface DD-IS may be defined as the rear surface (or lower surface). In the specification, an upper part (or upper side) and a lower part (or lower side) may be defined with respect to the third direction DR3, and the upper part (or upper side) may be defined as a direction approaching the display surface DD-IS, and the lower part (or lower side) may be defined as a direction away from the display surface DD-IS.

FIG. 2 is a schematic cross-sectional view of a part corresponding to virtual line I-I′ of FIG. 1. FIG. 2 is a schematic cross-sectional view of a display device according to an embodiment.

The display device DD may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

The display panel DP may be a component that generates a video. The display panel DP may be a light emitting display panel. For example, the display panel DP may be a quantum dot light emitting display panel including a quantum dot light emitting element.

The base layer BS may provide a base surface on which the circuit layer DP-CL is disposed. The base layer BS may be a rigid substrate; or the base layer BS may be a flexible substrate that is capable of bending, folding, rolling, and the like. The base layer BS may be a glass substrate, a metal substrate, a polymer substrate, or the like. However, embodiments are not limited thereto, and the base layer BS may include an inorganic layer, an organic layer, or a composite material layer.

The circuit layer DP-CL may be disposed on the base layer BS. The circuit layer DP-CL may include an insulation layer, a semiconductor pattern, a conductive pattern, a signal line, and the like. The insulation layer, a semiconductor layer, and a conductive layer may be formed on the base layer BS through coating, deposition, etc., and the insulation layer, the semiconductor layer, and the conductive layer may be selectively patterned through multiple cycles of a photolithography process. Thereafter, a semiconductor pattern, a conductive pattern, and a signal line included in the circuit layer DP-CL may be formed.

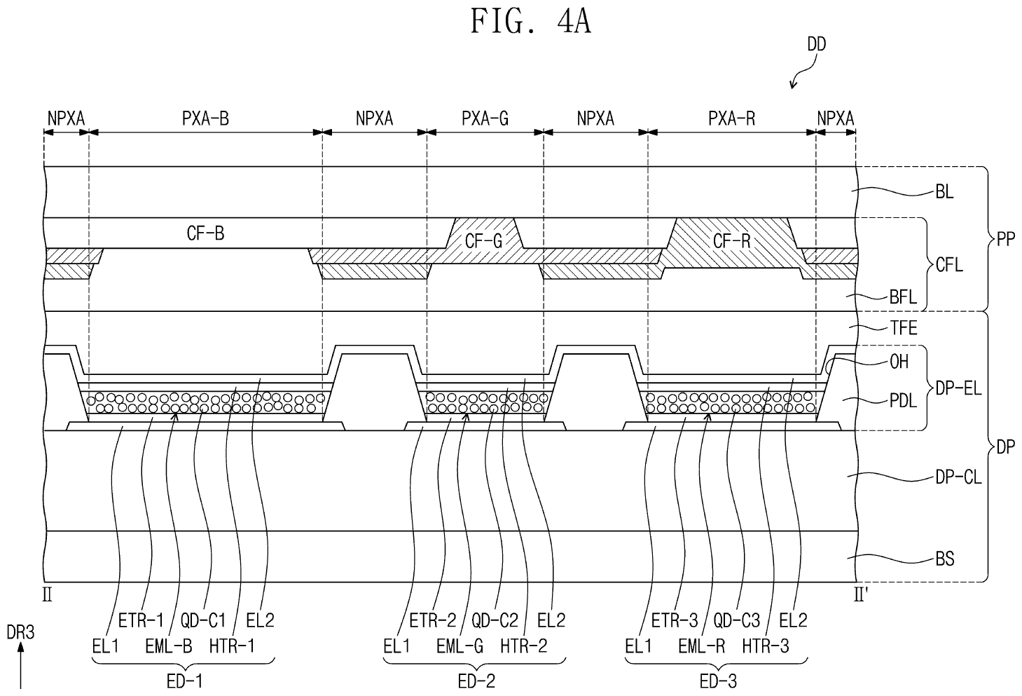

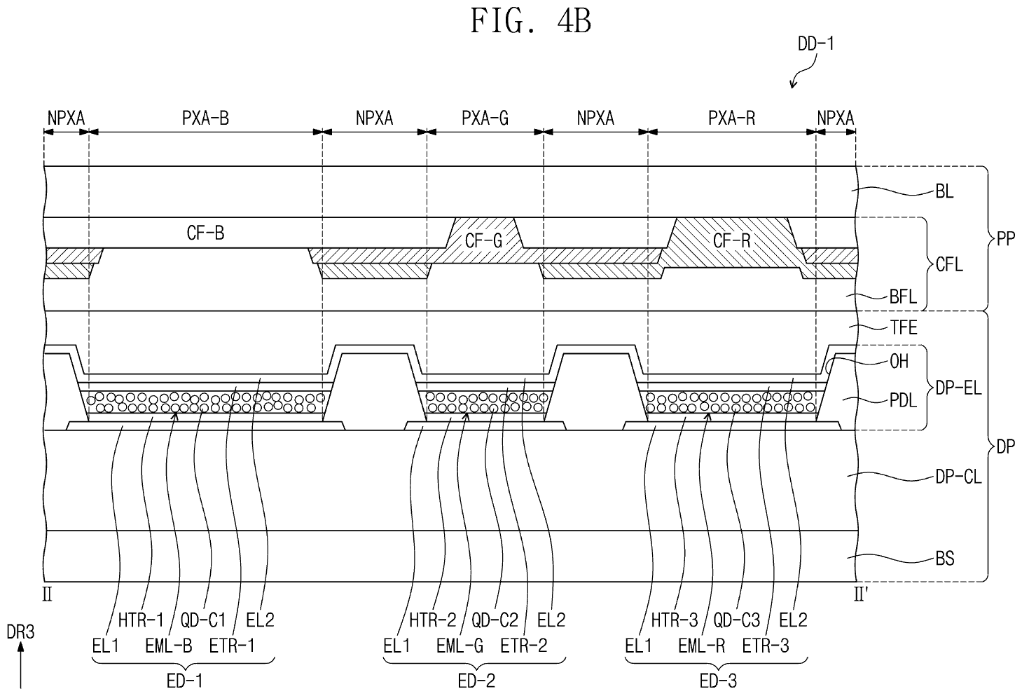

The display element layer DP-EL may be disposed on the circuit layer DP-CL. The display element layer DP-EL may include a pixel-defining film PDL (see FIGS. 4A and 4B) and first to third light-emitting elements ED-1, ED-2, and ED-3 (see FIGS. 4A and 4B), to be described later. For example, the display element layer DP-EL may include an organic light-emitting material, an inorganic light-emitting material, an organic-inorganic light-emitting material, quantum dots, quantum rods, a micro-LED, or a nano-LED. For example, the display element layer DP-EL may include quantum dots.

The encapsulation layer TFE may protect the display element layer DP-EL from moisture, oxygen, and foreign substances such as dust particles. The encapsulation layer TFE may include at least one inorganic layer. In an embodiment, the encapsulation layer TFE may have a structure where an inorganic layer, an organic layer, and an inorganic layer are stacked in sequence.

The optical layer PP may be disposed on the display panel DP, and may control light that is reflected at the display panel DP from an external light. The optical layer PP may include, for example, a polarizing layer, or include a color filter layer. Although not shown in the drawings, in an embodiment, the optical layer PP may also be omitted.

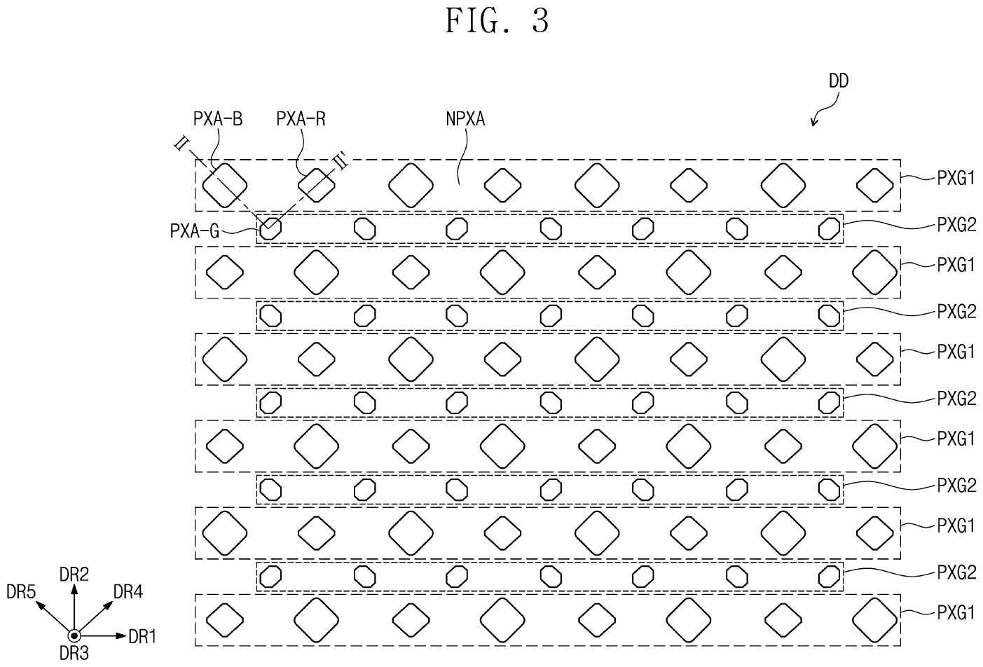

FIG. 3 is a schematic plan view of a display device according to an embodiment. FIG. 4A is a schematic cross-sectional view of a portion corresponding to virtual line II-II′ of FIG. 3. FIG. 3 may be a schematic plan view illustrating the display region DA (see FIG. 1) of the display device DD. FIG. 4A may be a schematic cross-sectional view illustrating a part of the display device DD according to an embodiment.

Referring to FIGS. 3 and 4A, the display device DD may include a peripheral region NPXA and light-emitting regions PXA-B, PXA-G, and PXA-R. The light-emitting regions PXA-B, PXA-G, and PXA-R may be regions where light respectively generated from light-emitting elements ED-1, ED-2, and ED-3 is emitted. The areas of the light-emitting regions PXA-B, PXA-G, and PXA-R may each have a different area, in which the area may be an area in a plan view.

The light-emitting regions PXA-B, PXA-G, and PXA-R may be arranged into groups according to the colors of light generated from the light-emitting elements ED-1, ED-2, and ED-3. FIGS. 3 and 4A illustrate three light-emitting regions PXA-B, PXA-G, and PXA-R respectively emitting blue light, green light, and red light. For example, the display device DD may include a blue light-emitting region PXA-B, a green light-emitting region PXA-G, and a red light-emitting region PXA-R that are distinguished from each other.

The display panel DP may include multiples of each of the light-emitting elements ED-1, ED-2, and ED-3 emitting light in different wavelength regions. The light-emitting elements ED-1, ED-2, and ED-3 may emit light having colors that are different from each other. For example, the display panel DP may include a first light-emitting element ED-1 that emits the blue light, a second light-emitting element ED-2 that emits the green light, and a third light-emitting element ED-3 that emits the red light. However, embodiments are not limited thereto, and the first to third light-emitting elements ED-1, ED-2, and ED-3 may emit light in a same wavelength region, or at least one light-emitting element may emit light in a wavelength region that is different from the remainder.

In the display device DD, according to an embodiment, as illustrated in FIGS. 3 and 4A, the light-emitting regions PXA-B, PXA-G, and PXA-R may have areas that are different in size or shape from each other, according to the colors of light emitted from light-emitting layers EML-B, EML-G, and EML-R of the light-emitting elements ED-1, ED-2, and ED-3. The blue light-emitting region PXA-B of the first light-emitting element ED-1 that emits the blue light may have a largest area, and the green light-emitting region PXA-G of the second light-emitting element ED-2 that emits the green light may have a smallest area. However, embodiments are not limited thereto, and the light-emitting regions PXA-B, PXA-G, and PXA-R may also emit light of colors other than red light, green light, and blue light. In an embodiment, the light-emitting regions PXA-B, PXA-G, and PXA-R may have a same area, or they may have areas that are provided at different proportions from what is illustrated in FIG. 3.

The light-emitting regions PXA-B, PXA-G, and PXA-R may be separated from each other by a pixel-defining film PDL. The peripheral regions NPXA may be regions disposed between the adjacent light-emitting regions PXA-B, PXA-G, and PXA-R and which may correspond to the pixel-defining film PDL. In an embodiment, the light-emitting regions PXA-B, PXA-G, and PXA-R may each correspond to a pixel.

The pixel-defining film PDL may define the light-emitting regions PXA-B, PXA-G, and PXA-R. The light-emitting regions PXA-B, PXA-G, and PXA-R may be separated from the peripheral regions NPXA by the pixel-defining film PDL.

The blue light-emitting regions PXA-B and the red light-emitting regions PXA-R may be alternately arranged along a first directional axis DR1 to form a first group PXG1. The green light-emitting regions PXA-G may be arranged along the first directional axis DR1 to form a second group PXG2. The first group PXG1 may be disposed apart from the second group PXG2 along a second directional axis DR2. The first group PXG1 and the second group PXG2 may each be provided in a repeating pattern. The first groups PXG1 and the second groups PXG2 may be alternately arranged along the second directional axis DR2.

A red light-emitting region PXA-R may be disposed apart from a green light-emitting region PXA-G along a fourth directional axis DR4. A blue light-emitting region PXA-B may be disposed apart from one green light-emitting region PXA-G along a fifth directional axis DR5. The fourth directional axis DR4 may be a direction between the first directional axis DR1 and the second directional axis DR2. The fifth directional axis DR5 may cross the fourth directional axis DR4, and may be a direction inclined toward the second directional axis DR2.

In an embodiment, an arrangement of the light-emitting regions PXA-B, PXA-G, and PXA-R is not limited to the arrangement illustrated in FIG. 3. For example, in an embodiment, the red light-emitting region PXA-R, the green light-emitting region PXA-G, and the blue light-emitting region PXA-B may be arranged in this order as a repeating sequence along the first directional axis DR1. In an embodiment, the shapes of each of the light-emitting regions PXA-B, PXA-G, and PXA-R in a plan view are not limited to what is illustrated in the drawing, and may each be defined in shapes that are different from what is illustrated.

In the display device DD (for example, as shown in FIG. 4A), a base layer BS may have a single-layered structure or a multilayered structure. In an embodiment, the base layer BS may include a first synthetic resin layer, an intermediate layer having a single-layered or a multilayered structure, and a second synthetic resin layer, which may be stacked in that order. The intermediate layer may be referred to as a base barrier layer. The intermediate layer may include a silicon oxide (SiOₓ) layer and an amorphous silicon (a-Si) layer disposed on the silicon oxide layer, but embodiments are not limited thereto. For example, the intermediate layer may include at least one of a silicon oxide layer, a silicon nitride layer, a silicon oxynitride layer, or an amorphous silicon layer.

The first and second synthetic resin layers may each include a polyimide-based resin. In an embodiment, the first and second synthetic resin layers may each independently include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the term “X-based resin” refers to a resin including an “X” functional group.

A circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of a display element layer DP-EL.

The display element layer DP-EL may include a pixel-defining film PDL and the first to third light-emitting elements ED-1, ED-2, and ED-3. The pixel-defining film PDL may have openings OH defined therein. The first to third light-emitting elements ED-1, ED-2, and ED-3 may be separated by the pixel-defining film PDL. Light-emitting layers EML-B, EML-G, and EML-R of the first to third light-emitting elements ED-1, ED-2, and ED-3 may each be separately disposed in the openings OH defined by the pixel-defining film PDL.

The pixel-defining film PDL may be formed of a polymer resin. For example, the pixel-defining film PDL may include a polyacrylate-based resin or a polyimide-based resin. In an embodiment, the pixel-defining film PDL may include an inorganic material other than the polymer resin. The pixel-defining film PDL may be formed by including a light-absorbing material, or formed by including black dye or black pigment. The pixel-defining film PDL including a black dye or a black pigment, may be implemented as a black pixel-defining film. When the pixel-defining film PDL is formed, carbon black, etc. may be used for the black dye or black pigment, but embodiments are not limited thereto.

In an embodiment, the pixel-defining film PDL may be formed of an inorganic material. For example, the pixel-defining film PDL may include an inorganic material such as silicon nitride (SiNₓ), silicon oxide (SiOₓ), or silicon oxynitride (SiOₓN_{y}).

The light-emitting elements ED-1, ED-2, and ED-3 may each include a first electrode EL1, the light-emitting layer EML-B, EML-G, or EML-R disposed on the first electrode EL1, a second electrode EL2 disposed on the light-emitting layer EML-B, EML-G, or EML-R, a hole transport region HTR-1, HTR-2, or HTR-3 disposed between the first electrode EL1 and the second electrode EL2, and an electron transport region ETR-1, ETR-2, or ETR-3 disposed between the first electrode EL1 and the second electrode EL2. The emission layers EML-B, EML-G, and EML-R may be respectively disposed between the electron transport region ETR-1, ETR-2, or ETR-3 and the hole transport region HTR-1, HTR-2, or HTR-3.

Referring to FIG. 4A, the light-emitting elements ED-1, ED-2, and ED-3 may each include the first electrode EL1, the electron transport region ETR-1, ETR-2, or ETR-3 disposed on the first electrode EL1, the light-emitting layer EML-B, EML-G, or EML-R disposed on the electron transport region ETR-1, ETR-2, or ETR-3, the hole transport region HTR-1, HTR-2, or HTR-3 disposed on the light-emitting layer EML-B, EML-G, or EML-R, and the second electrode EL2 disposed on the hole transport region HTR-1, HTR-2, or HTR-3. The electron transport region ETR-1, ETR-2, or ETR-3 may be disposed between the first electrode EL1 and the light-emitting layer EML-B, EML-G, or EML-R, and the hole transport region HTR-1, HTR-2, or HTR-3 may be disposed between the light-emitting layer EML-B, EML-G, or EML-R and the second electrode EL2.

At least a portion of the first electrode EL1 may be exposed in an opening OH of the pixel-defining film PDL. The first electrode EL1 may have conductivity. The first electrode EL1 may be formed of a metal material, a metal alloy, a conductive compound, or the like. The first electrode EL1 may be a cathode or an anode. However, an embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), etc. When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (for example, a mixture of Ag and Mg). In an embodiment, the first electrode EL1 may have a multilayered structure including a reflective film or transflective film formed of the above-mentioned materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but embodiments are not limited thereto. In an embodiment, the first electrode EL1 may include the above-described metal materials, a combination of at least two metal materials selected from the above-described metal materials, an oxide of the above-described metal materials, or the like. The first electrode EL1 may have a thickness in a range of about 700 Å to about 10,000 Å. For example, the thickness of the first electrode EL1 may be in a range of about 1000 Å to about 3,000 Å.

The second electrode EL2 may be a common electrode. The second electrode EL2 may be an anode or a cathode, but embodiments are not limited thereto. For example, when the first electrode EL1 is an anode, the second electrode EL2 may be a cathode, and when the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective film or transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of at least two metal materials selected from the above-described metal materials, an oxide of the above-described metal materials, or the like.

Although not shown in the drawings, the second electrode EL2 may be electrically connected to an auxiliary electrode. If the second electrode EL2 is electrically connected to the auxiliary electrode, resistance of the second electrode EL2 may be reduced.

The light-emitting layer EML-B, EML-G, or EML-R may each be disposed between the first electrode EL1 and the second electrode EL2. The first light-emitting element ED-1 may include a first light-emitting layer EML-B, the second light-emitting element ED-2 may include a second light-emitting layer EML-G, and the third light-emitting element ED-3 may include a third light-emitting layer EML-R. The first light-emitting layer EML-B may include a first quantum dot QD-C1. The second light-emitting layer EML-G may include a second quantum dot QD-C2. The third light-emitting layer EML-R may include a third quantum dot QD-C3.

The quantum dots QD-C1, QD-C2, and QD-C3, respectively included in the light-emitting layers EML-B, EML-G, and EML-R, may be stacked to form at least one layer. FIG. 4A shows that the quantum dots QD-C1, QD-C2, and QD-C3, having a circular cross-section, may be arranged to form approximately two layers, but embodiments are not limited thereto. For example, the arrangement of the quantum dots QD-C1, QD-C2, and QD-C3 may vary according to the thickness of the light-emitting layers EML-B, EML-G, and EML-R, the shape of the quantum dots QD-C1, QD-C2, and QD-C3 included in the light-emitting layers EML-B, EML-G, and EML-R, the average diameter of the quantum dots QD-C1, QD-C2, and QD-C3, and the like. In an embodiment, in the light-emitting layers EML-B, EML-G, and EML-R, the quantum dots QD-C1, QD-C2, and QD-C3 may be aligned adjacent to each other to form one layer, or aligned to form multiple layers such as two layers or three layers.

The first quantum dot QD-C1 of the first light-emitting element ED-1 may emit the blue light. The second quantum dot QD-C2 of the second light-emitting element ED-2 may emit the green light. The third quantum dot QD-C3 of the third light-emitting element ED-3 may emit the red light. The quantum dots QD-C1, QD-C2, and QD-C3 may each include a core (not shown) and a shell (not shown) surrounding the core. Accordingly, the quantum dots QD-C1, QD-C2, and QD-C3 may each have a core-shell structure. In an embodiment, the cores of the quantum dots QD-C1, QD-C2, and QD-C3 may include different materials. In another embodiment, the cores of the quantum dots QD-C1, QD-C2, and QD-C3 may include a same material. Any two cores among the cores of the quantum dots QD-C1, QD-C2, and QD-C3 may include a same material, and the remaining core may include a different material.

FIG. 4A shows that the diameters of the first to third quantum dots QD-C1, QD-C2, and QD-C3 may be similar to each other, but embodiments are not limited thereto. The diameters of the first to third quantum dots QD-C1, QD-C2, and QD-C3 may be different from each other. For example, the first quantum dot QD-C1 of the first light-emitting element ED-1, which emits light in a shorter wavelength region, may have a smaller average diameter than that of the second quantum dot QD-C2 of the second light-emitting element ED-2 and the third quantum dot QD-C3 of the third light-emitting element ED-3, which may each emit light in a longer wavelength region. In the specification, an average diameter may be an arithmetic mean of particle diameters of the quantum dots. In the specification, a particle diameter of a quantum dot may be an average value of the widths of the quantum dot particles as measured on a cross-section thereof.

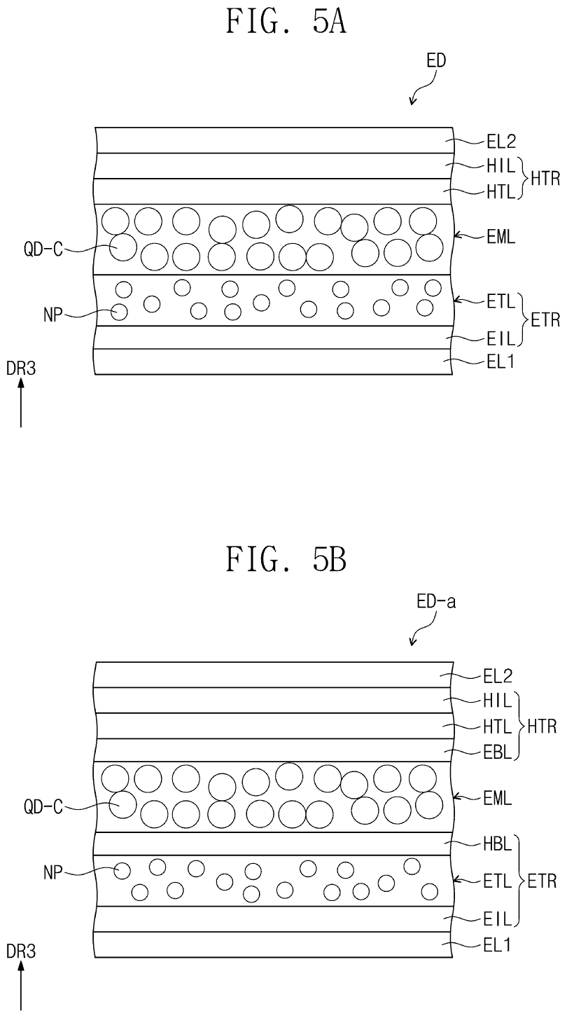

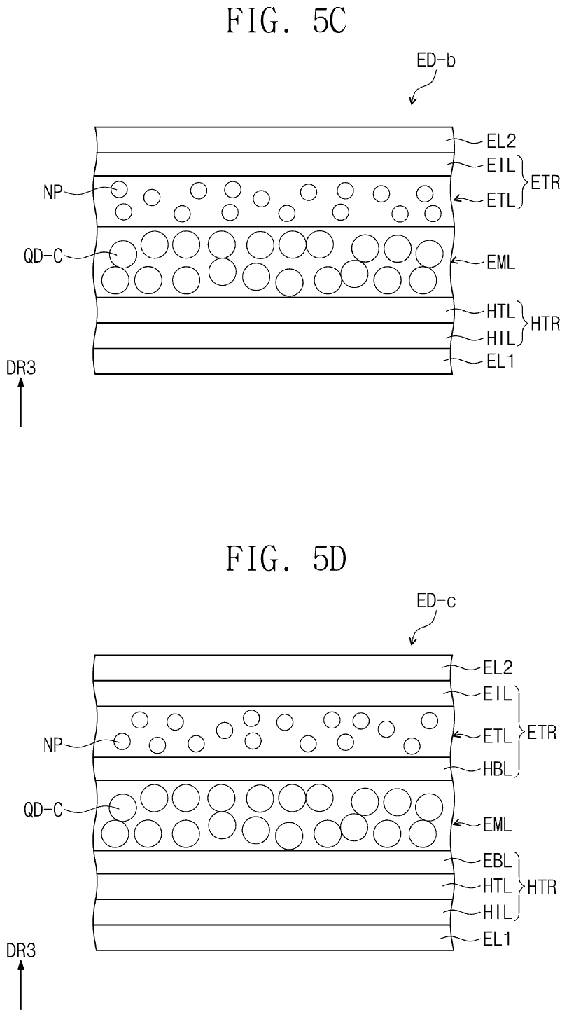

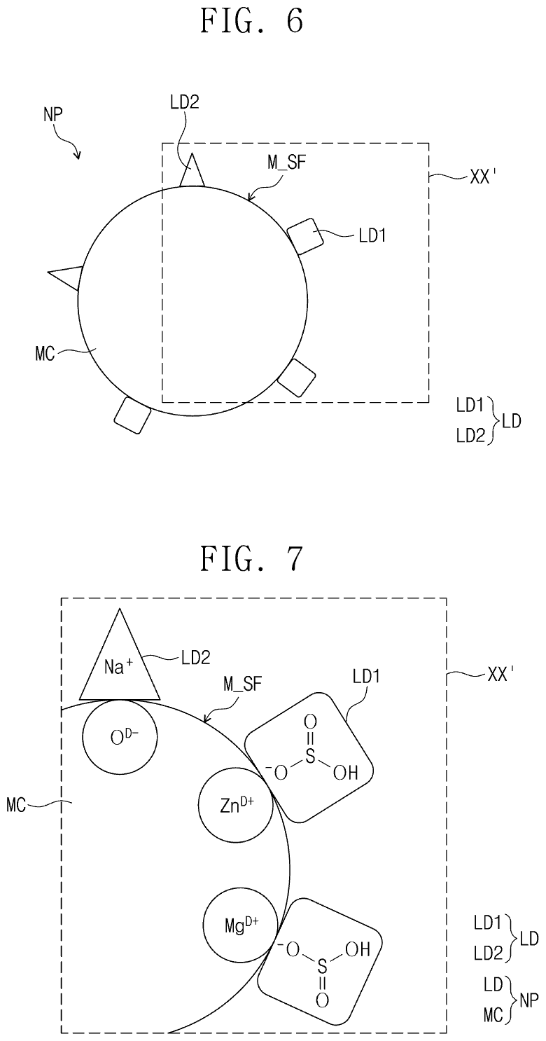

The electron transport region ETR-1, ETR-2, or ETR-3 may each be disposed between the first electrode EL1 and the light-emitting layer EML-B, EML-G, or EML-R. In an embodiment, the electron transport region ETR-1, ETR-2, or ETR-3 may each include a metal nanoparticle NP (see FIG. 6) to be described later. In an embodiment, the metal nanoparticle NP (see FIG. 6) may include a core MC (see FIG. 6) and a ligand LD (see FIG. 6) bonded to the core MC (see FIG. 6). The core MC (see FIG. 6) may include a metal oxide, and the ligand LD (see FIG. 6), derived from an ionic compound including bisulfite, may include the bisulfite. The metal nanoparticle NP (see FIG. 6), including bisulfite, may improve luminous efficiency of the light-emitting element ED-1, ED-2, or ED-3. The metal nanoparticle NP (see FIGS. 5A to 5D) will be described in more detail later.

The electron transport regions ETR-1, ETR-2, and ETR-3 of the first to third light-emitting elements ED-1, ED-2, and ED-3 may each be respectively disposed in the openings OH to be separated from each other. The first light-emitting element ED-1 may include a first electron transport region ETR-1, the second light-emitting element ED-2 may include a second electron transport region ETR-2, and the third light-emitting element ED-3 may include a third electron transport region ETR-3.

The first to third electron transport regions ETR-1, ETR-2, and ETR-3 may each independently have a structure consisting of a layer consisting of a single material, a structure consisting of a layer including different materials, or a structure including multiple layers including different materials. The first to third electron transport regions ETR-1, ETR-2, and ETR-3 may each independently have a thickness, for example, in a range of about 1,000 Å to about 1,500 Å.

In an embodiment, the first to third electron transport regions ETR-1, ETR-2, and ETR-3 may each further include an electron injection material and/or an electron transport material of the related art. For example, the first to third electron transport regions ETR-1, ETR-2, and ETR-3 may each independently include an anthracene-based compound. As another example, the first to third electron transport regions ETR-1, ETR-2, and ETR-3 may each independently include Alq₃ (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9, 10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O₈)-(1,1′-biphenyl-4-olato)aluminum), Bebq₂ (beryllium bis(benzoquinolin-10-olate)), ADN (9,10-di(naphthalen-2-yl)anthracene), BmPyPhB (1,3-bis[3,5-di(pyridin-3-yl)phenyl]benzene), and any mixture thereof. As another example, the first to third electron transport regions ETR-1, ETR-2, and ETR-3 may each independently include BCP (2,9-dimethyl-4,7-diphenyl-1,10-phenanthroline), TSPO1 (diphenyl(4-(triphenylsilyl)phenyl) phosphine oxide), Bphen (4,7-diphenyl-1,10-phenanthroline), etc.

The hole transport region HTR-1, HTR-2, or HTR-3 may each be disposed between the light-emitting layer EML-B, EML-G, or EML-R and the second electrode EL2. The hole transport regions HTR-1, HTR-2, and HTR-3 of the first to third light-emitting elements ED-1, ED-2, and ED-3 may be respectively disposed in the openings OH to be separated. The first light-emitting element ED-1 may include a first hole transport region HTR-1, the second light-emitting element ED-2 may include a second hole transport region HTR-2, and the third light-emitting element ED-3 may include a third hole transport region HTR-3. In an embodiment, the hole transport regions HTR-1, HTR-2, and HTR-3 may include an organic material.

The hole transport regions HTR-1, HTR-2, and HTR-3 may each independently have a structure consisting of a layer consisting of a single material, a structure consisting of a layer including different materials, or a structure including multiple layers including different materials. The first to third hole transport regions HTR-1, HTR-2, and HTR-3 may each independently have a thickness, for example, in a range of about 50 Å to about 15,000 Å. For example, the first to third hole transport regions HTR-1, HTR-2, and HTR-3 may each independently have a thickness in a range of about 100 Å to about 10,000 Å For example, the first to third hole transport regions HTR-1, HTR-2, and HTR-3 may each independently have a thickness in a range of about 100 Å to about 5,000 Å.

In an embodiment, the first to third hole transport regions HTR-1, HTR-2, and HTR-3 may each include a hole injection material and/or a hole transport material of the related art. For example, the first to third hole transport regions HTR-1, HTR-2, and HTR-3 may each independently include a phthalocyanine compound such as copper phthalocyanine, and include DNTPD(N¹,N¹′-([1,1′-biphenyl]-4,4′-diyl)bis(N¹-phenyl-N⁴,N⁴-di-m-tolylbenzene-1,4-diamine)), m-MTDATA (4,4′,4″-[tris(3-methylphenyl)phenylamino] triphenylamine), TDATA (4,4′,4″-tris(N,N-diphenylamino)triphenylamine), 2-TNATA (4,4′,4″-tris[N (2-naphthyl)-N-phenylamino]-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPB (N,N′-di(naphthalen-1-yl)-N,N′-diphenyl-benzidine), polyetherketone (TPAPEK) including triphenylamine, 4-isopropyl-4′-methyldiphenyliodonium [tetrakis(pentafluorophenyl) borate], HATCN (dipyrazino[2,3-f: 2′,3′-h] quinoxaline-2,3,6,7,10,11-hexacarbonitrile), etc.

In an embodiment, the first to third hole transport regions HTR-1, HTR-2, and HTR-3 may each independently include a carbazole-based derivative such as N-phenyl carbazole and polyvinyl carbazole, a fluorene-based derivative, a triphenylamine-based derivative such as TPD (N,N′-bis(3-methylphenyl)-N,N′-diphenyl-[1,1′-biphenyl]-4,4′-diamine) and TCTA (4,4′,4″-tris(N-carbazolyl)triphenylamine), NPB (N,N′-di(naphthalen-1-yl)-N,N′-diplienyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), CzSi(9-(4-tert-butylphenyl)-3,6-bis(triphenylsilyl)-9H-carbazole), CCP (9-phenyl-9H-3,9′-bicarbazole), mCP (1,3-bis(N-carbazolyl)benzene), mDCP (1,3-bis(1,8-dimethyl-9H-carbazol-9-yl)benzene), or the like.

An encapsulation layer TFE may include at least one inorganic film (hereinafter, inorganic encapsulation film). In an embodiment, the encapsulation layer TFE may include at least one organic film (hereinafter, organic encapsulation film) and at least one inorganic encapsulation film.

The inorganic encapsulation film may protect the display element layer DP-EL from moisture and/or oxygen, and the organic encapsulation film may protect the display element layer DP-EL from foreign substances such as dust particles. The inorganic encapsulation film may include silicon nitride, silicon oxynitride, silicon oxide, titanium oxide, aluminum oxide, or the like, but embodiments are not limited thereto. The organic encapsulation film may include an acrylate-based compound, an epoxy-based compound, etc. The organic encapsulation film may include a photopolymerizable organic material, but embodiments are not limited thereto.

An optical layer PP may include a base substrate BL and a color filter layer CFL. The base substrate BL may provide a base surface on which the color filter layer CFL is disposed. The base substrate BL may be a glass substrate, a metal substrate, or a plastic substrate. However, embodiments are not limited thereto, and the base substrate BL may include an inorganic layer, an organic layer, or a composite material layer.

The color filter layer CFL may include first to third filters CF-B, CF-G, and CF-R. The first to third filters CF-B, CF-G, and CF-R may be disposed to respectively correspond to the first to third light-emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed to respectively correspond to the first to third light-emitting regions PXA-B, PXA-G, and PXA-R.

The first to third filters CF-B, CF-G, and CF-R may each include a polymeric photosensitive resin and a pigment or dye. The first filter CF-B may include a blue pigment or a blue dye, the second filter CF-G may include a green pigment or a green dye, and the third filter CF-R may include a red pigment or a red dye. However, embodiments are not limited thereto, and the first filter CF-B may not include a pigment or dye. The first filter CF-B may include a polymeric photosensitive resin, and may not include a pigment or a dye. The first filter CF-B may be transparent. The first filter CF-B may be formed of a transparent photosensitive resin.

The color filter layer CFL may further include a buffer layer BFL. For example, the buffer layer BFL may serve as a protection layer for the first to third filters CF-B, CF-G, and CF-R. The buffer layer BFL may be an inorganic material layer that includes at least one of silicon nitride, silicon oxide, and silicon oxynitride. The buffer layer BFL may be formed of a single layer or of multiple layers.

In an embodiment, the second filter CF-G and the third filter CF-R may each be a yellow filter. The second filter CF-G and the third filter CF-R may not be separated, may be provided as a unitary filter.

Although not shown in the drawings, the color filter layer CFL may further include a light-blocking part (not shown). The light-blocking part (not shown) may be a black matrix. The light-blocking part may include an organic light-blocking material or inorganic light-blocking material each including a black pigment or a black dye. The light-blocking part (not shown) may prevent light leakage, and may set boundaries between the filters CF-B, CF-G, and CF-R that are adjacent to each other.

FIG. 4B is a schematic cross-sectional view of a display device according to another embodiment. In the description of FIG. 4B, features that have been described with respect to FIGS. 1 to 4A will not be explained again, and the different features will be described.

In comparison to the display device DD in FIG. 4A, a display device DD-1 in FIG. 4B is different at least in that the positions of the electron transport regions ETR-1, ETR-2, and ETR-3 and the hole transport regions HTR-1, HTR-2, and HTR-3 may be different. Referring to FIG. 4B, light-emitting elements ED-1, ED-2, and ED-3 may each include a first electrode EL1, the hole transport region HTR-1, HTR-2, or HTR-3 disposed on the first electrode EL1, a light-emitting layer EML-B, EML-G, or EML-R disposed on the hole transport region HTR-1, HTR-2, or HTR-3, the electron transport region ETR-1, ETR-2, or ETR-3 disposed on the light-emitting layer EML-B, EML-G, or EML-R and a second electrode EL2 disposed on the electron transport region ETR-1, ETR-2, or ETR-3. The electron transport region ETR-1, ETR-2, or ETR-3 may be disposed between the light-emitting layer EML-B, EML-G, or EML-R, and the second electrode EL2, and the hole transport region HTR-1, HTR-2, or HTR-3 may be disposed between the first electrode EL1 and the light-emitting layer EML-B, EML-G, or EML-R.

FIGS. 5A to 5D are respectively a schematic cross-sectional view of light-emitting elements ED, ED-a, ED-b, and ED-c according to embodiments. Referring to FIGS. 5A to 5D, the light-emitting elements ED, ED-a, ED-b, and ED-c may each include a first electrode EL1, a light-emitting layer EML disposed on the first electrode EL1, a second electrode EL2 disposed on the light-emitting layer EML, a hole transport region HTR disposed between the first electrode EL1 and the second electrode EL2, and an electron transport region ETR disposed between the first electrode EL1 and the second electrode EL2. The electron transport region ETR may be spaced apart from the hole transport region HTR with the light-emitting layer EML therebetween.

At least one of the first to third light-emitting elements ED-1, ED-2, and ED-3 illustrated in FIG. 4A may each independently have a structure according to the light-emitting elements ED and ED-a, as described with reference to FIGS. 5A and 5B. At least one of the first to third light-emitting elements ED-1, ED-2, and ED-3 illustrated in FIG. 4B may each independently have a structure according to the light-emitting elements ED-b and ED-c, as described with reference to FIGS. 5C and 5D.

Referring to FIGS. 5A and 5B, the light-emitting elements ED and ED-a may each include the first electrode EL1, the electron transport region ETR, the light-emitting layer EML, the hole transport region HTR, and the second electrode EL2, stacked in that sequence. In the light-emitting elements ED and ED-a, the electron transport region ETR may include a metal nanoparticle NP according to an embodiment.

Referring to FIG. 5A, the hole transport region HTR may include a hole injection layer HIL and a hole transport layer HTL. The hole transport layer HTL may be disposed on the light-emitting layer EML, and the hole injection layer HIL may be disposed on the hole transport layer HTL. The electron transport region ETR may include an electron injection layer EIL and an electron transport layer ETL. The electron injection layer EIL may be disposed on the first electrode EL1, the electron transport layer ETL may be disposed on the electron injection layer EIL, and the light-emitting layer EML may be disposed on the electron transport layer ETL. Although not shown in the drawings, in an embodiment, the electron injection layer EIL may be omitted.

The light-emitting element ED-a in FIG. 5B may be different from the light-emitting element ED in FIG. 5A at least in that the hole transport region HTR may further include an electron-blocking layer EBL, and in that the electron transport region ETR may further include a hole-blocking layer HBL. The electron-blocking layer EBL may be disposed on the light-emitting layer EML. The electron-blocking layer EBL may be disposed between the light-emitting layer EML and the hole transport layer HTL. The hole-blocking layer HBL may be disposed on the electron transport layer ETL. The hole-blocking layer HBL may be disposed between the light-emitting layer EML and the electron transport layer ETL. Although not shown in the drawings, in an embodiment, any one of the electron-blocking layer EBL and the hole-blocking layer HBL may be omitted.

The light-emitting elements ED-b and ED-c, shown in FIGS. 5C and 5D, may be different from the light-emitting elements ED and ED-a shown in FIGS. 5A and 5B at least in that the positions of the hole transport region HTR and the electron transport region ETR may be different. Referring to FIGS. 5C and 5D, the light-emitting elements ED-b and ED-c may each include a first electrode EL1, a hole transport region HTR, a light-emitting layer EML, an electron transport region ETR, and a second electrode EL2, stacked in that sequence. In the light-emitting element ED-b or ED-c, the electron transport region ETR may include a metal nanoparticle NP according to an embodiment.

Referring to FIG. 5C, the hole transport region HTR may include a hole injection layer HIL and the hole transport layer HTL. The hole injection layer HIL may be disposed on the first electrode EL1, and the hole transport layer HTL may be disposed on the hole injection layer HIL. The electron transport region ETR may include an electron injection layer EIL and the electron transport layer ETL. The electron transport layer ETL may be disposed on the light-emitting layer EML, and the electron injection layer EIL may be disposed on the electron transport layer ETL. Although not shown in the drawings, in an embodiment, the electron injection layer EIL may be omitted.

Referring to FIG. 5D, the hole transport region HTR may further include an electron-blocking layer EBL, and the electron transport region ETR may further include a hole-blocking layer HBL. The electron-blocking layer EBL may be disposed between the hole transport layer HTL and the light-emitting layer EML. The hole-blocking layer HBL may be disposed between the light-emitting layer EML and the electron transport layer ETL.

Referring to FIGS. 5A to 5D, the electron transport region ETR may include the metal nanoparticle NP according to an embodiment. At least one of the electron injection layer EIL, the electron transport layer ETL, and the hole-blocking layer HBL may each independently include the metal nanoparticle NP according to an embodiment. For example, the electron transport layer ETL may include the metal nanoparticle NP according to an embodiment. In an embodiment, at least one of the hole-blocking layer HBL and the electron injection layer EIL may each independently include the metal nanoparticle NP according to an embodiment. In another embodiment, the hole-blocking layer HBL, the electron transport layer ETL, and the electron injection layer EIL may each independently include the metal nanoparticle NP according to an embodiment. The electron transport region ETR, including the metal nanoparticle NP according to an embodiment, may maintain excellent electron injection and/or electron transport characteristics, and may also reduce or prevent charge imbalance, thereby contributing to improvement of luminous efficiency of the light-emitting elements ED, ED-a, ED-b, and ED-c. The metal nanoparticle NP according to an embodiment will be described in detail later.

The light-emitting layer EML may include a quantum dot QD-C. The first to third quantum dots QD-C1, QD-C2, and QD-C3 as illustrated in FIGS. 4A and 4B may be the same or substantially similar to the quantum dot QD-C as explained in the following descriptions. The quantum dot QD-C may not include cadmium.

In the specification, the quantum dot QD-C may be a crystal of a semiconductor compound. The quantum dot QD-C may emit light in various light-emitting wavelengths according to a size of crystal. A diameter of the quantum dot QD-C may be, for example, in a range of about 1 nm to about 10 nm.

The quantum dot QD-C may be synthesized through a wet chemical process, a metal organic chemical vapor deposition process, a molecular beam epitaxy process, or a similar process thereto. In the wet chemical process, an organic solvent and a precursor material are mixed, and a particle crystal of the quantum dot QD-C is grown. When the crystal grows, the organic solvent may serve as a dispersant coordinated on a crystal surface of the quantum dot QD-C, and may control the growth of the crystal. Accordingly, the wet chemical process may control the growth of the quantum dot QD-C particles through a process that may be more readily performed and at a lower cost than vapor deposition methods, such as the metal organic chemical vapor deposition (MOCVD) or molecular beam epitaxy (MBE).

In embodiments, the quantum dot may include a Group II-VI semiconductor compound, a Group I-II-VI semiconductor compound, a Group II-IV-VI semiconductor compound, a Group I-II-IV-VI semiconductor compound, a Group III-V semiconductor compound, a Group III-VI semiconductor compound, a Group I-III-VI semiconductor compound, a Group IV-VI semiconductor compound, a Group II-IV-V semiconductor compound, a Group IV element or compound, or any combination thereof. In the specification, the term “Group” refers to a group in the IUPAC periodic table.

Examples of a Group II-VI semiconductor compound may include: a binary compound such as ZnS, ZnSe, ZnTe, ZnO, HgS, HgSe, HgTe, MgSe, and MgS; a ternary compound such as ZnSeS, ZnSeTe, ZnSTe, HgSeS, HgSeTe, HgSTe, HgZnS, HgZnSe, HgZnTe, MgZnSe, and MgZnS; a quaternary compound such as HgZnSeS, HgZnSeTe, and HgZnSTe; and any combination thereof.

In an embodiment, a Group II-VI semiconductor compound may further include a Group I element and/or a Group IV element. Examples of a Group I-II-VI compound may include CuSnS or CuZnS. Examples of a Group II-IV-VI compound may include ZnSnS, etc. Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and any combination thereof.

Examples of a Group III-V semiconductor compound may include: a binary compound such as GaN, GaP, GaAs, GaSb, AlN, AIP, AlAs, AlSb, InN, InP, InAs, and InSb; a ternary compound such as GaNP, GaNAs, GaNSb, GaPAs, GaPSb, AlNP, AlNAs, AlNSb, AIPAS, AlPSb, InGaP, InNP, InAlP, InNAs, InNSb, InPAs, and InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; and any combination thereof. In an embodiment, a Group III-V semiconductor compound may further include a Group II element. Examples of a Group III-V semiconductor compound further including a Group II element may include InZnP, InGaZnP, InAlZnP, etc.

Examples of a Group III-VI semiconductor compound may include: a binary compound such as GaS, Ga₂S₃, GaSe, Ga₂Se₃, GaTe, InS, InSe, In₂Se₃, and InTe; a ternary compound such as InGaS₃ and InGaSe₃; and any combination thereof.

Examples of a Group I-III-VI semiconductor may include: a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂; a quaternary compound such as AgInGaS₂ and AgInGaSe₂; and any combination thereof.

Examples of a Group IV-VI semiconductor compound may include: a binary compound such as SnS, SnSe, SnTe, PbS, PbSe, and PbTe; a ternary compound such as SnSeS, SnSeTe, SnSTe, PbSeS, PbSeTe, PbSTe, SnPbS, SnPbSe, and SnPbTe; a quaternary compound such as SnPbSSe, SnPbSeTe, and SnPbSTe; and any combination thereof.

Examples of a Group II-IV-V semiconductor compound may include a ternary compound such as ZnSnP, ZnSnP₂, ZnSnAs₂, ZnGeP₂, ZnGeAs₂, and any combination thereof.

Examples of a Group IV element or compound may include: a single element material such as Si and Ge; a binary compound such as SiC and SiGe; and any combination thereof.

Each element included in a compound, such as a binary compound, a ternary compound, or a quaternary compound, may exist in a particle at a uniform or at a non-uniform concentration. For example, a formula may indicate the elements that are included in the compound, but an elemental ratio within the compound may vary. For example, AgInGaS₂ may indicate AgInₓGa₁₋ₓS₂ (where x is a real number between 0 and 1).

In an embodiment, the quantum dot QD-C may have a single structure where each element included in the corresponding quantum dot QD-C has a uniform concentration, or the quantum dot QD-C may have a core-shell structure. For example, a material included in the core and a material included in the shell may be different from each other.

The shell of the quantum dot QD-C may serve as a protection layer that maintains semiconductor characteristics by preventing chemical denaturation of the core, and/or may serve as a charging layer that imparts electrophoretic characteristics to the quantum dot. The shell may have a single layer or multiple layers. A quantum dot that has a core/shell structure may have a concentration gradient in which the concentration of the element existing in the shell decreases toward the core.

Examples of a shell of the quantum dot QD-C may include a metal oxide, a non-metal oxide, a semiconductor compound, and any combination thereof. Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; and any combination thereof. Examples of a semiconductor compound may include: as described in the specification, a Group III-VI semiconductor compound; a Group II-VI semiconductor compound; a Group III-V semiconductor compound; a Group III-VI semiconductor compound; a Group I-III-VI semiconductor compound; a Group IV-VI semiconductor compound; and any combination thereof. For example, the semiconductor compound may include ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or a combination thereof.

The quantum dot QD-C may have a full width at half maximum (FWHM) of a light-emitting spectrum less than or equal to about 45 nm. For example, the quantum dot QD-C may have a FWHM of an emission spectrum less than or equal to about 40 nm. For example, the quantum dot QD-C may have a FWHM of an emission spectrum less than or equal to about 30 nm. When the FWHM of the quantum dot QD-C falls within any of the above ranges, color purity or color reproducibility may be improved. Light emitted through the quantum dot QD-C may be emitted in every direction, thereby improving a wide viewing angle. The quantum dot QD-C may have any form or shape that is used in the related art. For example, the quantum dot QD-C may be in the form of nanoparticles, nanotubes, nanowires, nanofibers, nano plate-shape particles, etc., or the quantum dot QD-C may have a circular shape, a pyramidal shape, a multi-arm shape, or a cubic shape.

By controlling a size of the quantum dot QD-C or controlling an elemental ratio in the compound consisting of the quantum dot QD-C, an energy band gap may be controlled, so that the light-emitting layer EML including the quantum dot QD-C may have light in various wavelength ranges. Accordingly, by using the above-described quantum dot QD-C (of different sizes or different elemental ratios in the quantum-dot compound), the light-emitting elements ED, ED-a, ED-b, and ED-c that emit light of various wavelength ranges may be achieved. For example, the size of the quantum dot QD-C or the elemental ratio in the compound consisting of the quantum dot QD-C may be adjusted to emit red light, green light, and/or blue light. In an embodiment, the quantum dots QD-C may be configured to emit white light by combining light of various colors.

FIG. 6 is a schematic cross-sectional view of a metal nanoparticle NP according to an embodiment. In an embodiment, the metal nanoparticle NP may include a core MC and a ligand LD bonded to the core MC. FIG. 6 shows five ligands LD as an example, but the number of ligands LD is not limited thereto. The position to which the ligand LD is bonded, as shown in FIG. 6, is only an example, and embodiments are not limited thereto.

In an embodiment, the core MC of the metal nanoparticle NP may include a metal oxide. In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1.

Zn_{(1-q)}Me_{q}O [Formula M-1]

In Formula M-1, q may be a real number from 0 to 0.5. In Formula M-1, Me may be Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba. For example, the core MC of the metal nanoparticle NP may include ZnMgO. However, this is only an example, and embodiments are not limited thereto.

In an embodiment, the ligand LD of the metal nanoparticle NP may include bisulfite derived from an ionic compound represented by Formula A-1. The ionic compound, represented by Formula A-1, may include metal cations and bisulfite anions.

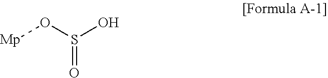

In Formula A-1, [symbol] represents an ionic bond. In Formula A-1, Mp may be Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba. In Formula A-1, Mp may correspond to the metal cations, and —OS(═O) OH may correspond to the bisulfite anions.

Referring to FIG. 6, the ligand LD may include a first ligand LD1 and a second ligand LD2. The ligand LD, derived from the ionic compound represented by Formula A-1, may include the first ligand LD1 and the second ligand LD2 generated by dissociation of ionic bonding from the ionic compound of Formula A-1. The first ligand LD1 may include the bisulfite anion in Formula A-1, and the second ligand LD2 may include metal cations. For example, the second ligand LD2 may include Mp in Formula A-1. Although not shown in the drawings, in an embodiment, the second ligand LD2 may be omitted.

In the metal nanoparticle NP, the first ligand LD1 and the second ligand LD2 may each be bonded to a surface M_SF of the core MC. FIG. 7 is an enlarged schematic view of region XX′ of FIG. 6. FIG. 7 may illustrate the ligand LD that is bonded to the surface M_SF of the core MC. FIG. 7 shows that the core MC may include metal oxides consisting of zinc, magnesium, and oxygen, and the ligand LD may include sodium cations (Na⁺) and bisulfite anions.

On the surface M_SF of the core MC, the metal oxide elements, included in the core MC, may be exposed. For example, zinc, magnesium, and oxygen may be exposed on the surface M_SF of the core MC, and the ligand LD may be bonded to at least one of zinc or magnesium. In an embodiment, the ligand LD may also be bonded to oxygen. The first ligand LD1 may be bonded to at least one of zinc and magnesium on the surface M_SF of the core MC. The second ligand LD2 may be bonded to oxygen on the surface M_SF of the core MC.

Zinc, magnesium, and oxygen, exposed on the surface M_SF of the core MC, may each include a dangling bond. In FIG. 7, the dangling bonds of zinc, magnesium, and oxygen are respectively denoted as Zn^{D+}, Mg^{D+}, and O^{D-}. The dangling bonds, which are the outermost electrons not participating in bonding, may correspond to surface defects of the core MC, and the surface defects of the core MC may be resolved by the ligands LD being bonded thereto. The first ligand LD1, including bisulfite anions, may be bonded to at least one of a zinc dangling bond (Zn^{D+}) and a magnesium dangling bond (Mg^{D+}) on the surface M_SF of the core MC. Oxygen, bonded to a sulfur atom and including a negative charge, in the bisulfite anions, may be bonded to at least one of the zinc dangling bond (Zn^{D+}) and the magnesium dangling bond (Mg^{D+}). The oxygen bonded to the sulfur atom and including the negative charge, in the bisulfite anions, may be directly bonded to the surface M_SF of the core MC. The second ligand LD2 that includes sodium ions may be bonded to the oxygen dangling bond (O^{D-}) on the surface M_SF of the core MC.

The metal nanoparticle NP, which includes the bisulfite ions bonded to the core MC, may maintain excellent electron injection and excellent electron transport characteristics, and may reduce or prevent charge imbalance in the light-emitting layer EML (see FIGS. 5A to 5D). In a light-emitting element of the related art, when an electron transport region includes a metal nanoparticle consisting of a core and a ligand, and a hole transport region includes an organic material, charge imbalance may occur in the light-emitting layer. Due to excessive injection of electrons into the light-emitting layer, auger recombination, which corresponds to non-light-emitting recombination, was increased, thereby causing decrease in luminous efficiency of the light-emitting element. The Auger recombination corresponds to a recombination of holes and electrons that does not result in light emission, and the energy of recombination may raise the energy of other holes and/or electrons. In contrast, the metal nanoparticle NP according to an embodiment may include bisulfite bonded to the core MC, and may thus resolve defects of the core MC and may prevent the excessive injection of electrons, thereby improving the luminous efficiency of the light-emitting element ED, ED-a, ED-b, or ED-C (see FIGS. 5A to 5D).

In an embodiment, a number of moles of bisulfite may be in a range of about 5 mol % to about 20 mol %, based on 100 mol % of a total number of moles of the metal nanoparticle. When the number of moles of bisulfite is less than or equal to about 5 mol %, based on 100 mol % of a total number of moles of the metal nanoparticle, defects of the core and charge imbalance in the light-emitting layer may not be resolved, so that the luminous efficiency of the light-emitting element may not improve. When the number of moles of bisulfite is greater than or equal to about 20 mol %, based on 100 mol % of a total number of moles of the metal nanoparticle, bisulfite may be excessively included, and the excessive bisulfite may have highly insulating characteristics, thereby causing the characteristic of the light-emitting element to deteriorate. In contrast, the metal nanoparticle NP according to an embodiment may include bisulfite in a range of about 5 mol % to about 20 mol %, based on 100 mol % of a total number of moles of the metal nanoparticle NP, so that the luminous efficiency of the light-emitting element ED, ED-a, ED-b, or ED-c (see FIGS. 5A to 5D) may be improved.

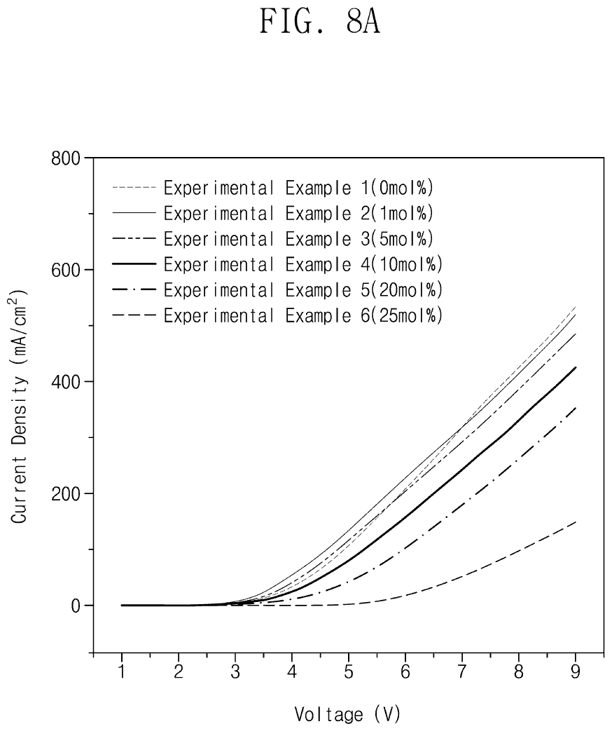

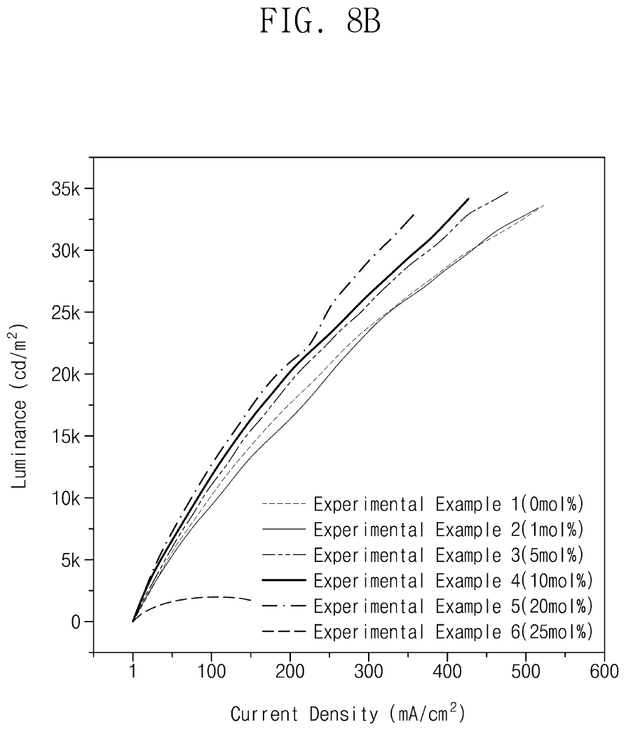

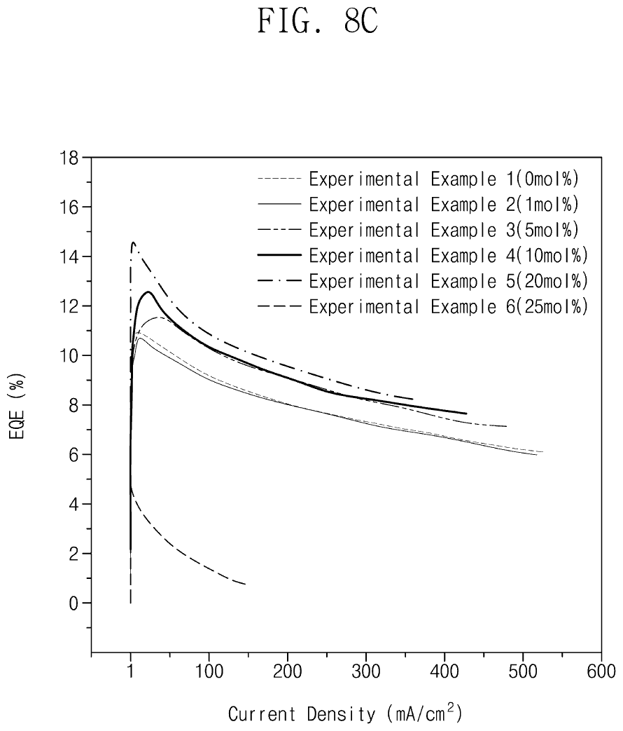

FIGS. 8A to 8C are graphs of the results of evaluating light-emitting elements in Experimental Example 1 to Experimental Example 6 which differ in the number of moles of bisulfite based on 100 mol % of a total number of moles of metal nanoparticle. In FIGS. 8A to 8C, the light-emitting elements in Experimental Example 1 to Experimental Example 6 may have the same configuration, except for the number of moles of the bisulfite. The graphs of FIGS. 8A to 8C show the results of evaluation using the CS-2000A spectroradiometer, a product of Konica Minolta, where the Keithley 2400 is connected.

In FIGS. 8A to 8C, the light-emitting elements in Experimental Example 1 to Experimental Example 6 were manufactured by the following method. A glass substrate, on which ITO of about 15 Ω/cm² (about 1,000 Å thickness) was patterned, was cut into a size of about 50 mm×50 mm×0.7 mm, and was ultrasonically cleansed using isopropyl alcohol and pure water for about 5 minutes each, and cleansed by irradiation with UV light for about 30 minutes and exposure to ozone.

A hole injection layer was formed by depositing poly(ethylenedioxythiophene):polystyrenesulfonate (PEDOT:PSS) at a thickness of about 400 Å, and a hole transport layer was formed by depositing poly[(9,9-dioctylfluorenyl-2,7-diyl)-co-(4,4′-(N-(4-secbutylphenyl)) diphenylamine)] (TFB) at a thickness of about 300 Å. ZnSeTe quantum dots were deposited on the hole transport layer to form a light-emitting layer having a thickness of about 120 Å. Metal oxides or metal nanoparticles were provided onto the light-emitting layer to form an electron transport layer having a thickness of about 400 Å. Al was deposited on the electron transport layer to form a second electrode having a thickness of about 1,000 Å, thereby completing the manufacturing of the light-emitting element.

In FIGS. 8A to 8C, the light-emitting element in Experimental Example 1 was manufactured by providing metal nanoparticles that do not include bisulfite, so that the metal nanoparticles are a metal oxide containing ZnMgO. The light-emitting element in Experimental Example 1 includes the metal nanoparticles which were manufactured by providing about 10 mmol of ZnMgO and not providing bisulfite.

The light-emitting elements in Experimental Example 2 to Experimental Example 6 were manufactured by providing metal nanoparticles including bisulfite, and the metal nanoparticles have a metal oxide core that includes ZnMgO. The light-emitting elements in Experimental Example 2 to Experimental Example 6 include the metal nanoparticles manufactured by providing about 10 mmol of ZnMgO, and by respectively providing about 1 mmol, about 5 mmol, about 10 mmol, about 20 mmol, or about 25 mmol of bisulfite. In the light-emitting elements in Experimental Example 2 to Experimental Example 6, the bisulfite is derived from solidum bisulfite. For example, the bisulfite is derived from an ionic compound represented by Formula A-1 where Mp is Na.

In the light-emitting element in Experimental Example 2, about 1 mmol of bisulfite was provided, and in the light-emitting element in Experimental Example 3, about 5 mmol of bisulfite was provided. In the light-emitting element in Experimental Example 4, about 10 mmol of bisulfite was provided, and in the light-emitting element in Experimental Example 5, about 20 mmol of bisulfite was provided. In the light-emitting element in Experimental Example 6, about 25 mmol of bisulfite was provided. In the light-emitting elements in Example 3 to Example 5, the number of moles of bisulfite is in a range of about 5 mol % to about 20 mol %, based on 100 mol % of a total number of moles of the metal nanoparticle. For example, the light-emitting elements in Experimental Example 3 to Experimental Example 5 satisfy the range of the number of moles of bisulfite according to an embodiment.

FIG. 8A is a graph showing the results of evaluating current density (mA/cm²) according to a driving voltage (V) in the light-emitting elements in Experimental Example 1 to Experimental Example 6. Referring to FIG. 8A, compared to the light-emitting element in Experimental Example 1, it may be seen that the light-emitting elements in Experimental Example 2 to Experimental Example 5 have a good current density according to the driving voltage. It may be seen that the light-emitting element in Experimental Example 6 has a relatively low current density according to the driving voltage. The light-emitting element in Experimental Example 6 includes bisulfite of about 25 mol % based on 100 mol % of the total number of moles of the metal nanoparticle, which is an excessive amount of bisulfite. Due to highly insulating characteristics of the excessive bisulfite, the light-emitting element in Experimental Example 6 has the low current density.

FIG. 8B is a graph showing the results of evaluating the luminance (cd/m²) according to the current density (mA/cm²) in the light-emitting elements in Experimental Example 1 to Experimental Example 6. FIG. 8C is a graph showing the results of evaluating the external quantum efficiency (EQE, %) according to the current density (mA/cm²) in the light-emitting elements in Experimental Example 1 to Experimental Example 6. Table 1 shows the max luminance (cd/m²) values of Experimental Example 1 to Experimental Example 6 in FIG. 8B and the max EQE (%) values of Experimental Example 1 to Experimental Example 6 in FIG. 8C.

TABLE 1

| | Max luminance | Max |
|---|---|---|
| | (cd/m²) | EQE (%) |
| Experimental Example 1 (0 mol %) | 33666 | 10.6 |
| Experimental Example 2 (1 mol %) | 33322 | 10.5 |
| Experimental Example 3 (5 mol %) | 34605 | 11.4 |
| Experimental Example 4 (10 mol %) | 34074 | 12.4 |
| Experimental Example 5 (20 mol %) | 32839 | 14.4 |
| Experimental Example 6 (25 mol %) | 1544 | 4.8 |

Referring to FIG. 8B and Table 1, it may be seen that the light-emitting elements in Experimental Example 1 to Experimental Example 5 have a good luminance. Referring to FIG. 8C and Table 1, it may be seen that the light-emitting elements in Experimental Example 3 to Experimental Example 5 have excellent external quantum efficiency, compared to the light-emitting element in Experimental Example 1. Referring to FIGS. 8A to 8C and Table 1 together, it may be seen that based on 100 mol % of a total number of moles of the metal nanoparticle, the light-emitting element including bisulfite in a range of about 5 mol % to about 20 mol % has excellent luminous efficiency while maintaining good current density and luminance. Accordingly, in an embodiment, it may be seen that the light-emitting element including bisulfite in a range of about 5 mol % to about 20 mol %, based on 100 mol % of a total number of moles of the metal nanoparticle, has excellent luminous efficiency.

The light-emitting element in Experimental Example 2 includes bisulfite, but the bisulfite is less than or equal to about 5 mol %, based on 100 mol % of a total number of moles of the metal nanoparticle. Accordingly, the light-emitting element in Experimental Example 2 may not have improved external quantum efficiency.

The light-emitting element in Experimental Example 6 includes bisulfite, but the bisulfite is greater than or equal to about 20 mol %, based on 100 mol % of a total number of moles of the metal nanoparticle. As previously described, the light-emitting element in Experimental Example 6 including an excessive amount of bisulfite has highly insulating characteristics, thereby having the low luminance and low external quantum efficiency.

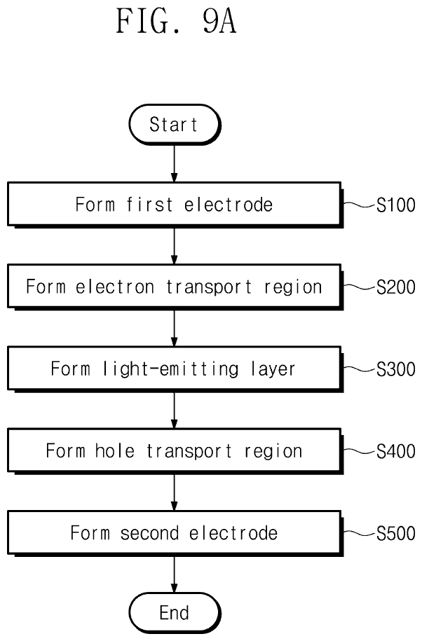

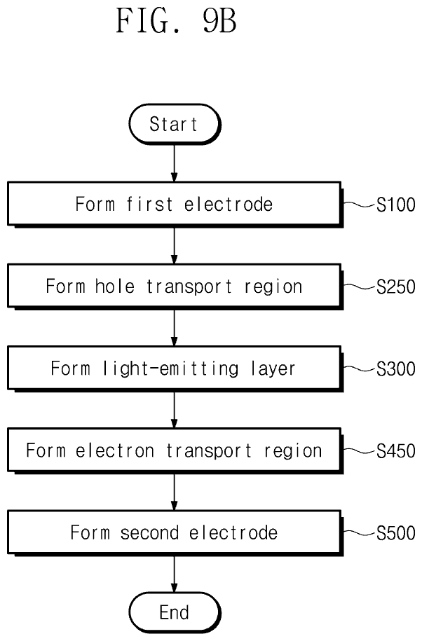

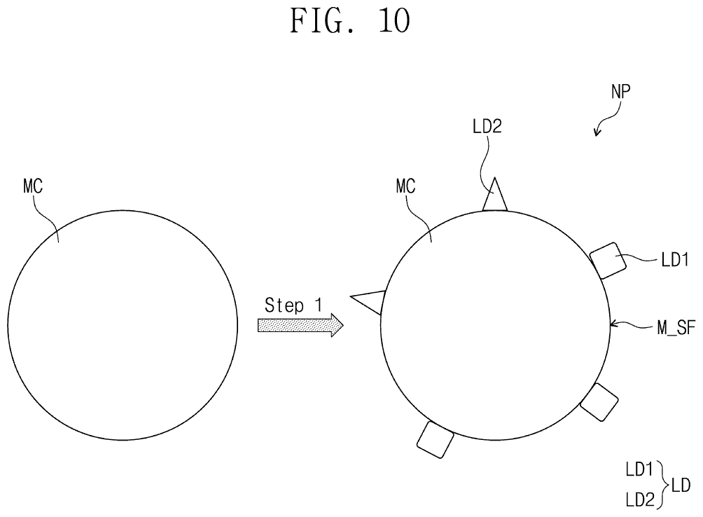

The light-emitting element according to an embodiment may be manufactured in a method for manufacturing a light-emitting element according to an embodiment. FIGS. 9A and 9B are flowcharts of the method for manufacturing the light-emitting element according to an embodiment. FIGS. 10 to 12 are schematic drawings of the steps of manufacturing the light-emitting element according to an embodiment. Hereinafter, for descriptions of FIGS. 9A to 12, the features that have been explained with reference to FIGS. 1 to 8C will not be explained again, and the differing features will be described.

Referring to FIGS. 9A and 9B, a method for manufacturing the light-emitting element according to an embodiment may include forming a first electrode (S100), forming a light-emitting layer on the first electrode (S300), forming a second electrode on the light-emitting layer (S500), forming a hole transport region (S400 and S250), and forming an electron transport region (S200 and S450).

In an embodiment, any one of the steps of forming the electron transport region (S200 or S450) and the step of forming the hole transport region (S400 or S250) may be performed between the step of forming the first electrode (S100) and the step of forming the light-emitting layer (S300), and the remaining step may be performed between the step of forming the light-emitting layer (S300) and the step of forming the second electrode (S500). FIG. 9A shows that the step of forming the electron transport region (S200) is performed between the step of forming the first electrode (S100) and the step of forming the light-emitting layer (S300), and the step of forming the hole transport region (S400) is performed between the step of forming the light-emitting layer (S300) and the step of forming the second electrode (S500). In contrast, FIG. 9B shows that the step of forming the hole transport region (S250) is performed between the step of forming the first electrode (S100) and the step of forming the light-emitting layer (S300), and the step of forming the electron transport region (S450) is performed between the step of forming the light-emitting layer (S300) and the step of forming the second electrode (S500).

The method for manufacturing the light-emitting element according to an embodiment may include producing a metal nanoparticle NP before the step of forming the electron transport region (S200 or S450). FIG. 10 is a schematic drawing of the step of producing the metal nanoparticle NP.

In an embodiment, the step of producing the metal nanoparticle NP may include producing a core MC and providing an ionic compound represented by Formula A-1, previously described, to the core MC to thereby produce the metal nanoparticle NP. A ligand LD may be bonded to a surface M_SF of the core MC by providing the ionic compound. In FIG. 10, ‘Step 1’ may represent the step of providing the ionic compound that is represented by Formula A-1.

In an embodiment, the core MC may include a metal oxide. The step of producing the core MC may include preparing a solution including a first metal precursor having a first metal, a second metal precursor having a second metal, and a first solvent, and providing a second solvent to the solution. The first metal and the second metal may be different from each other. The first metal and the second metal may each independently include Li, Be, Na, Mg, Al, K, Ca, Ta, Ti, V, Cr, Mn, Fe, Co, Ni, Cu, Ga, Ge, Rb, Sr, Zr, Nb, Mo, Ru, Rh, Pd, Ag, In, Sn, Sb, or Ba. In the specification, the metal precursor may be a material which contains a metal and an element chemically bonded to the metal, and the element chemically bonded to the metal may be an element that readily dissociates from the metal. In an embodiment, the metal precursor may be provided as a type of salt.

In an embodiment, the core MC may include ZnMgO. The first metal precursor may be a zinc precursor, and the second metal precursor may be a magnesium precursor. The zinc precursor and the magnesium precursor may each independently include acetate ions or halogen ions. The halogen ions may include at least one of fluoride ions, bromide ions, chloride ions, and iodide ions. The acetate ions and the halogen ions may each be chemically bonded to zinc and/or magnesium.

The first metal precursor and the second metal precursor may each be provided by being dissolved in the first solvent. The first solvent may be a polar solvent. The first solvent may include at least one of ethanol and dimethyl sulfoxide (DMSO). However, embodiments are not limited thereto, and any solvent may be used as the first solvent without limitation, as long as it is a solvent in which the first and second metal precursors may each be readily dissolved.

The second solvent may be provided to the solution including the first metal precursor, the second metal precursor, and the first solvent. The second solvent may include at least one of potassium hydroxide, sodium hydroxide, trimethylammonium hydroxide (TMAM), and tetramethylammonium hydroxide (TMAH). Ethanol may further be provided together with the providing of the second solvent. Thus, the core MC including the metal oxide may be formed.

The ionic compound, represented by Formula A-1, may be provided to the formed core MC. The surface M_SF of the core MC may be treated with the ionic compound. Accordingly, the ligands LD may be bonded to the surface M_SF by reacting with zinc, magnesium, and oxygen exposed on the surface M_SF of the core MC. After the ligands LD are bonded to the core MC, the metal nanoparticle NP may be separated from the mixture. The separated metal nanoparticles NP may be dispersed in a third solvent CV (see FIG. 12), so that a composition COP (see FIG. 12) for forming the electron transport region ETR (see FIGS. 5A to 5D) may be produced.

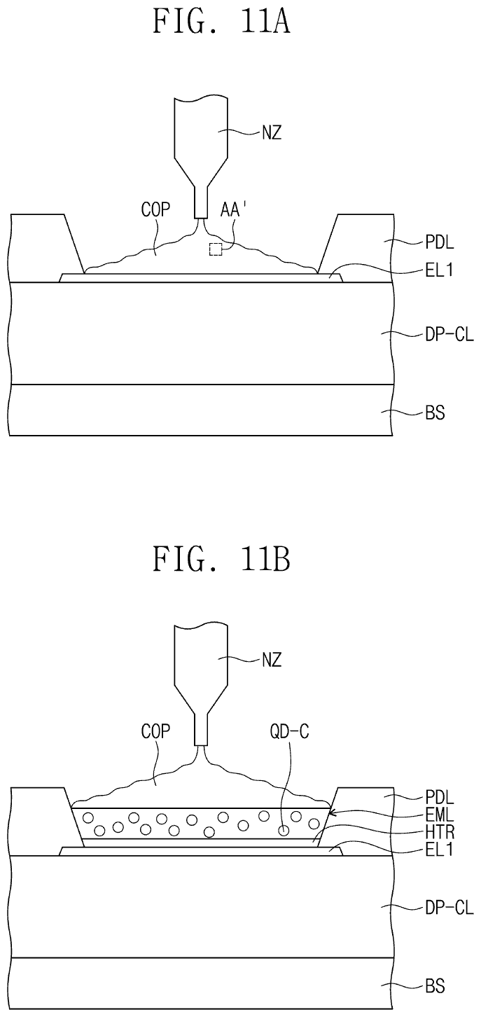

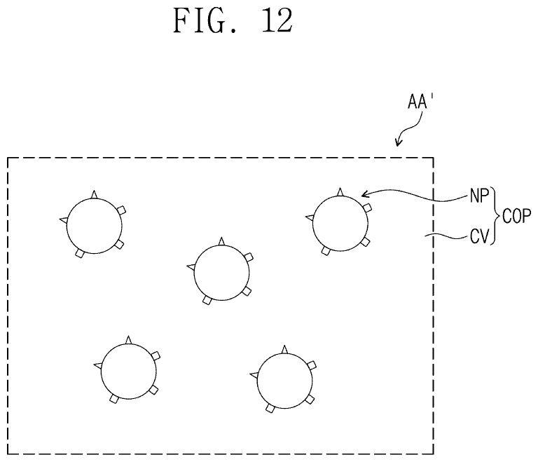

FIG. 11A is a schematic drawing of a step of providing a composition COP onto a first electrode EL1 to form the electron transport region ETR (see FIGS. 5A to 5D). The first electrode EL1 may be formed on a base layer BS. For example, the first electrode EL1 may be formed on a circuit layer DP-CL disposed on the base layer BS. FIG. 11B is a drawing illustrating a step of providing a composition COP onto a light-emitting layer EML. FIG. 11B may be different from FIG. 11A at least in that the step of forming the light-emitting layer EML is performed before the step of providing the composition COP.

In an embodiment that performs the manufacturing step illustrated in FIG. 11A, the light-emitting elements ED and ED-a, illustrated in FIGS. 5A and 5B, may be manufactured. After the electron transport region ETR (see FIGS. 5A and 5B) is formed by providing the composition COP including the metal nanoparticle NP (see FIG. 12), the light-emitting layer EML (see FIGS. 5A and 5B), the hole transport region HTR (see FIGS. 5A and 5B), and the second electrode EL2 (see FIGS. 5A and 5B) may be formed in sequence. In an embodiment that performs the manufacturing step illustrated in FIG. 11B, the light-emitting elements ED-b or ED-c illustrated in FIGS. 5C and 5D may be manufactured. After the electron transport region ETR (see FIGS. 5C and 5D) is formed by providing the composition COP including the metal nanoparticle NP (see FIG. 12), the second electrode EL2 (see FIGS. 5C and 5D) may be formed.

Referring to FIG. 11B, a quantum-dot composition including quantum dots QD-C may be provided onto the hole transport region HTR to form the light-emitting layer EML. The quantum-dot composition may include the quantum dots QD-C and a solvent where the quantum dots QD-C are dispersed. For example, the quantum dots QD-C may be dispersed in an organic solvent, and may thus be provided through an inkjet printing method or a dispensing method.

FIG. 12 is an enlarged schematic view of region AA′ of FIG. 11A, and may schematically show the composition COP. Hereinafter, description on the composition COP may be equally applied to FIGS. 11A and 11B. Hereinafter, the description will be made with reference to FIGS. 10 to 12.

In an embodiment, the composition COP including the metal nanoparticles NP may be provided through an inkjet printing method or a dispensing method. FIGS. 11A and 11B show that the composition COP may be provided through a nozzle NZ, but the device for providing the composition COP is not limited thereto.

In an embodiment, the metal nanoparticle NP may include a core MC, and a ligand LD bonded to a surface M_SF of the core MC. The core MC may include a metal oxide represented by Formula M-1, and the ligand LD may include bisulfite anions derived from an ionic compound represented by Formula A-1. Accordingly, the metal nanoparticle NP may have excellent discharge stability, and the composition COP including the metal nanoparticles NP may be provided through an inkjet printing method or a dispensing method. A method for manufacturing a light-emitting element according to an embodiment may include the step of providing the composition COP including the metal nanoparticles NP, thereby exhibiting excellent manufacturing efficiency.

The composition COP may include a third solvent CV where the metal nanoparticles NP are dispersed. Any solvent may be used as the third solvent CV without limitation, as long as it is a solvent in which the metal nanoparticles NP are readily dispersed.

A method for manufacturing a light-emitting element according to an embodiment may include the step of providing a composition including metal nanoparticles to form an electron transport region, and the step of providing quantum dots to form a light-emitting layer. The composition including the metal nanoparticles may be provided through an inkjet printing method or a dispensing method. The light-emitting element according to an embodiment, formed in the method for manufacturing the light-emitting element according to an embodiment, may include the electron transport region including the metal nanoparticles and the light-emitting layer including the quantum dots. A display device according to an embodiment may include the light-emitting element according to an embodiment.

In an embodiment, the metal nanoparticle may include a core and a ligand bonded to a surface of the core. The core may include a metal oxide, and the ligand may be derived from an ionic compound including bisulfite. The ligand may include bisulfite anions. The metal nanoparticles including the bisulfite anions may maintain excellent electron injection and electron transport characteristics, and may reduce or prevent charge imbalance in the light-emitting layer. Accordingly, the light-emitting element including the metal nanoparticles according to an embodiment may exhibit excellent luminous efficiency. The display device according to an embodiment, including the light-emitting element according to an embodiment, may exhibit excellent display efficiency.

A light-emitting element according to an embodiment and a display device including the light-emitting element may exhibit excellent luminous efficiency by including metal nanoparticles consisting of ligands including bisulfite ions.

A method for manufacturing a light-emitting element according to an embodiment may exhibit excellent manufacturing efficiency by including a step of providing the metal nanoparticle consisting of the ligands including bisulfite ions.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a light-emitting layer disposed on the first electrode, the light-emitting layer including a quantum dot;
a second electrode disposed on the light-emitting layer;
a hole transport region disposed between the first electrode and the second electrode; and
an electron transport region disposed between the first electrode and the second electrode, the electron transport region including a metal nanoparticle, wherein
the light-emitting layer is disposed between the hole transport region and the electron transport region,
the metal nanoparticle includes:
a core including a metal oxide; and
a ligand bonded to the core, the ligand including bisulfite derived from an ionic compound represented by Formula A-1: 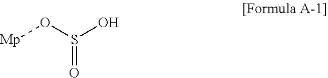
wherein in Formula A-1,
Mp is Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba, and [symbol]
represents an ionic bond.

2. The light-emitting element of claim 1, wherein the ligand comprises:
a first ligand including the bisulfite in Formula A-1; and
a second ligand including Mp in Formula A-1.

3. The light-emitting element of claim 2, wherein the first ligand and the second ligand are each bonded to a surface of the core.

4. The light-emitting element of claim 1, wherein a number of moles of the bisulfite is in a range of about 5 mol % to about 20 mol %, based on 100 mol % of a total number of moles of the metal nanoparticle.

5. The light-emitting element of claim 1, wherein:
the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or
the metal oxide is represented by Formula M-1:
Zn_{(1-q)}Me_{q}O [Formula M-1]
wherein in Formula M-1,
q is a real number from 0 to 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba.

6. The light-emitting element of claim 1, wherein the quantum dot does not comprise cadmium.

7. The light-emitting element of claim 1, wherein
the hole transport region is disposed between the first electrode and the light-emitting layer, and
the electron transport region is disposed between the light-emitting layer and the second electrode.

8. The light-emitting element of claim 1, wherein
the hole transport region is disposed between the light-emitting layer and the second electrode, and
the electron transport region is disposed between the first electrode and the light-emitting layer.

9. A method for manufacturing a light-emitting element, comprising:
forming a first electrode;
forming a light-emitting layer on the first electrode;
forming a second electrode on the light-emitting layer;
forming a hole transport region; and
forming an electron transport region by providing a composition including a metal nanoparticle, wherein
one step among the forming of the hole transport region and the forming of the electron transport region is performed between the forming of the first electrode and the forming of the light-emitting layer, and the remaining step is performed between the forming of the light-emitting layer and the forming of the second electrode, and
the metal nanoparticle includes:
a core including a metal oxide, and
a ligand bonded to the core, the ligand including bisulfite derived from an ionic compound represented by Formula A-1: 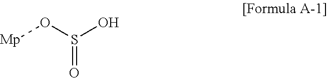
wherein in Formula A-1,
Mp is Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba, and [symbol]
represents an ionic bond.

10. The method of claim 9, further comprising:
producing the metal nanoparticle before the forming of the electron transport region, wherein
the producing of the metal nanoparticle includes:
producing the core; and
providing the ionic compound to the core to produce the metal nanoparticle in which the ligand is bonded to a surface of the core.

11. The method of claim 10, wherein
the producing of the core comprises:
preparing a solution including a first metal precursor including a first metal, a second metal precursor including a second metal different from the first metal, and a first solvent; and
providing, to the solution, a second solvent different from the first solvent, and
first metal and the second metal each independently includes Li, Be, Na, Mg, Al, K, Ca, Ta, Ti, V, Cr, Mn, Fe, Co, Ni, Cu, Ga, Ge, Rb, Sr, Zr, Nb, Mo, Ru, Rh, Pd, Ag, In, Sn, Sb, or Ba.

12. The method of claim 11, wherein
the first metal precursor is a zinc precursor,
the second metal precursor is a magnesium precursor, and
zinc precursor and the magnesium precursor each independently comprise an acetate ion or a halogen ion.

13. The method of claim 11, wherein the first solvent comprises at least one of ethanol and dimethyl sulfoxide (DMSO).

14. The method of claim 11, wherein the second solvent comprises at least one of potassium hydroxide, sodium hydroxide, trimethylammonium hydroxide (TMAM), and tetramethylammonium hydroxide (TMAH).

15. The method of claim 9, wherein a number of moles of the bisulfite is in a range of about 5 mol % to about 20 mol %, based on 100 mol % of a total number of moles of the metal nanoparticle.

16. The method of claim 9, wherein the composition is provided through an inkjet printing method or a dispensing method.

17. A display device comprising:
a display element layer disposed on a base layer, the display element layer including a light-emitting element, wherein
the light-emitting element includes:
a first electrode;
a light-emitting layer disposed on the first electrode, the light-emitting layer including a quantum dot;
a second electrode disposed on the light-emitting layer;
a hole transport region disposed between the first electrode and the second electrode; and
an electron transport region disposed between the first electrode and the second electrode, the electron transport region including a metal nanoparticle,
the light-emitting layer is disposed between the hole transport layer and the electron transport region, and
the metal nanoparticle includes:
a core including a metal oxide, and
a ligand bonded to the core, the ligand including bisulfite derived from an ionic compound represented by Formula A-1: 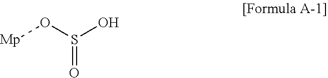
wherein in Formula A-1,
Mp is Zn, Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba, and [symbol]
represents an ionic bond.

18. The display device of claim 17, wherein the ligand comprises:
a first ligand including the bisulfite in Formula A-1; and
a second ligand including Mp in Formula A-1.

19. The display device of claim 18, wherein the first ligand and the second ligand are each bonded to a surface of the core.

20. The display device of claim 17, wherein a number of moles of the bisulfite is in a range of about 5 mol % to about 20 mol %, based on 100 mol % of a total number of moles of the metal nanoparticle.

21. The display device of claim 17, wherein:
the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or
the metal oxide is represented by Formula M-1:
Zn_{(1-q)}Me_{q}O [Formula M-1]
wherein in Formula M-1,
q is a real number from 0 to 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Rh, Pd, Ag, In, Sn, Sb, or Ba.
